(19) United States
(12) Patent Application Publication
(10) Pub. No.: US 2016/0372490 A1
(43) Pub. Date: Dec. 22, 2016

(54) ARRAY SUBSTRATE AND MANUFACTURING METHOD THEREOF, AND DISPLAY PANEL

(71) Applicants: BOE TECHNOLOGY GROUP CO., LTD., Beijing (CN); ORDOS YUANSHENG OPTOELECTRONICS CO., LTD., Ordos, Innner Mongolia (CN)

(72) Inventors: Jie ZHANG, Beijing (CN); Fuqiang LI, Beijing (CN)

(21) Appl. No.: 14/907,635

(22) PCT Filed: May 19, 2015
(86) PCT No.: PCT/CN2015/079320

§ 371 Date: Jan. 26, 2016

(30) Foreign Application Priority Data
Jan. 26, 2015 (CN) 201510038705.7

(51) Int. Cl. H01L 27/12

(52) U.S. Cl. CPC H01L 27/124; H01L 27/1248; H01L 27/1259

(57) ABSTRACT

An array substrate and a manufacturing method thereof, and a display panel are provided. The array substrate comprises: a base substrate (1), including a display region and a non-display region; and a metal conductive layer, an insulating layer (3) located above the metal conductive layer and an auxiliary conductive layer located above the insulating layer (3), formed on the base substrate (1), sequentially, wherein the metal conductive layer includes a plurality of first conducting lines (2), and the auxiliary conductive layer includes a plurality of second conducting lines (4), each of the plurality of first conducting lines (2) corresponding to at least one of the plurality of second conducting lines (4), each of the plurality of second conducting lines (4) is electrically connected with the corresponding first conducting line (2) through a connecting structure (51, 52) in the insulating layer (3), and a vertical projection of the connecting structure (51, 52) is located in the non-display region. Embodiments of the present disclosure can realize a narrow-frame display panel and are easily implemented, thereby reducing difficulty in fabricating the narrow-frame display panel.

### TECHNICAL FIELD

Embodiments of the present disclosure relate to an array substrate and a manufacturing method thereof, and a display panel.

### BACKGROUND

Nowadays, a flat-panel display device has become a current mainstream display product due to factors such as light weight, thinness, low radiation and so on. For a display panel of the flat-panel display device, a narrow-frame display panel has a beautiful appearance and is conducive to obtain a large-sized spliced display product, and therefore a narrow-frame design of the display panel has become a major trend in development of the display field.

Currently, a narrow frame of the display panel is mainly implemented by manners of: firstly, reducing line width and line spacing of signal lines in a non-display region of the display panel; secondly, reducing a number of elements or sizes of the elements in a gate driving circuit, so as to compress a space occupied by the gate driving circuit.

However, for the first manner, since its implementation is limited by certain aspects such as alignment error, mura defect and process stability and so on, it is difficult to significantly save space occupied by the signal lines in the non-display region of the display panel; and in the second manner, in order to reduce the number of elements or the sizes of elements in the gate driving circuit, it is necessary to consider signal stability and antistatic capacity, so it is difficult to improve the gate driving circuit.

### SUMMARY

Embodiments of the present disclosure provide an array substrate and a manufacturing method thereof, and a display panel, which can realize a narrow-frame display panel and be easily implemented, thereby reducing difficulty in fabricating the narrow-frame display panel.

In one aspect, an embodiment of the present disclosure provides an array substrate, comprising: a base substrate, including a display region and a non-display region; and a metal conductive layer, an insulating layer located above the metal conductive layer and an auxiliary conductive layer located above the insulating layer, formed on the base substrate, sequentially, wherein the metal conductive layer includes a plurality of first conducting lines, and the auxiliary conductive layer includes a plurality of second conducting lines, each of the plurality of first conducting lines corresponds to at least one of the plurality of second conducting lines, each of the plurality of second conducting lines is electrically connected with a corresponding first conducting line through a connecting structure in the insulating layer, and a vertical projection of the connecting structure is located in the non-display region.

In another aspect, an embodiment of the present disclosure provides a display panel, comprising: an array substrate provided as above; and an opposed substrate, cell-assembled with the array substrate.

In still another aspect, an embodiment of the present disclosure provides a manufacturing method of an array substrate, comprising: preparing a base substrate, wherein the base substrate includes a display region and a non-display region; forming a metal conductive layer on the base substrate, the metal conductive layer including a plurality of first conducting lines; forming an insulating layer above the metal conductive layer, a plurality of connecting structures being formed in the insulating layer, and vertical projections of the connecting structures being located in the non-display region; and forming an auxiliary conductive layer above the insulating layer, the auxiliary conductive layer comprising a plurality of second conducting lines, and the second conducting line being electrically connected with the corresponding first conducting line through the connecting structure.

### BRIEF DESCRIPTION OF THE DRAWINGS

In order to clearly illustrate the technical solution of the embodiments of the present disclosure, the drawings of the embodiments will be briefly described in the following; it is obvious that the described drawings are only related to some embodiments of the present disclosure and thus are not limitative to the present disclosure.

FIG. 1 is a structural schematic diagram of an array substrate provided by an embodiment of the disclosure;

FIG. 2 is a structural schematic diagram of an insulating layer provided by an embodiment of the disclosure;

FIG. 3 is a structural schematic diagram of a first array substrate provided by an embodiment of the present disclosure;

FIG. 4 is a structural schematic diagram of a second array substrate provided by an embodiment of the present disclosure; and

FIG. 5 is a structural schematic diagram of a third array substrate provided by an embodiment of the present disclosure.

### DETAILED DESCRIPTION

In order to make objects, technical details and advantages of the embodiments of the present disclosure apparent, the technical solutions of the embodiment will be described in a clearly and fully understandable way in connection with the drawings related to the embodiments of the present disclosure. It is obvious that the described embodiments are just a part but not all of the embodiments of the present disclosure. Based on the described embodiments of the present disclosure, those ordinarily skilled in the art can obtain other embodiment(s), without any inventive work, which should be within the protective scope of the present disclosure.

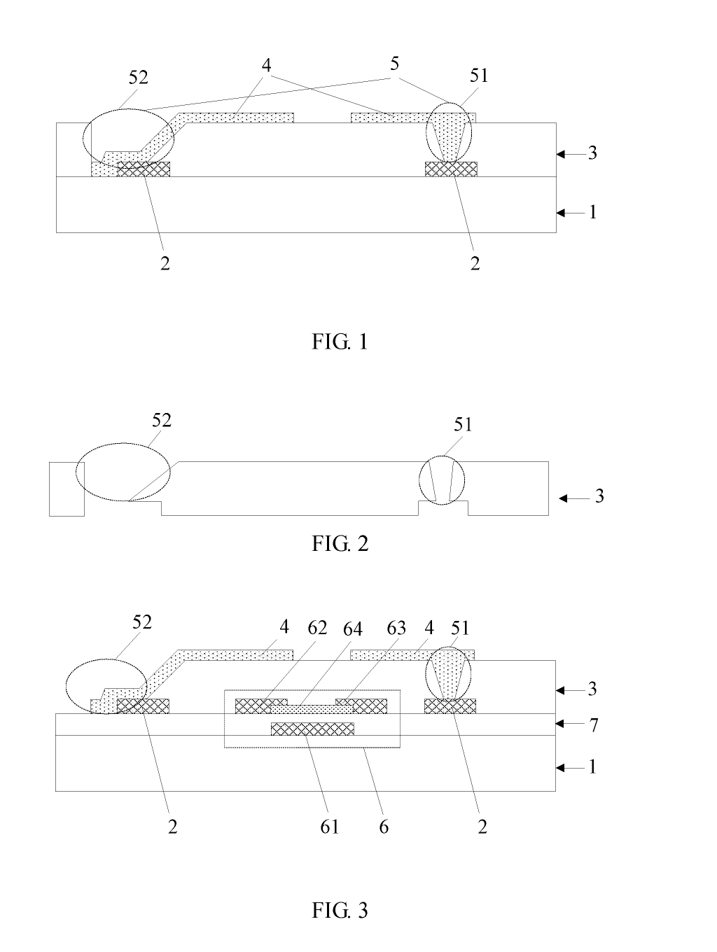

Referring to FIG. 1, an embodiment of the present disclosure provides an array substrate, comprising: a base substrate 1, including a display region and a non-display region; and a metal conductive layer, an insulating layer 3 located above the metal conductive layer and an auxiliary conductive layer located above the insulating layer 3, which are formed on the base substrate 1, sequentially; the metal conductive layer includes a plurality of first conducting lines 2, and the auxiliary conductive layer includes a plurality of second conducting lines 4, each of the plurality of first conducting lines 2 corresponding to at least one of the plurality of second conducting lines 4; the second conducting line 4 is electrically connected with the corresponding first conducting line 2 through a connecting structure 5 in the insulating layer 3, and a vertical projection of the connecting structure 5 is located in the non-display region.

Here, it should be noted that, the vertical projection refers to a projection in a thickness direction of the array substrate.

In an embodiment of the present disclosure, each of the first conducting lines 2 may at least include a portion located in the non-display region, and further, the first conducting line 2 may further include a portion located in the display region, and the second conducting line 4 is electrically connected with the corresponding first conducting line 2 through the connecting structure 5 in the insulating layer 3, which may be that the second conducting line 4 is electrically connected with the portion of the corresponding first conducting line 2 located in the non-display region.

In the embodiment of the present disclosure, the first conducting line 2 of the metal conductive layer of the array substrate extends to the auxiliary conductive layer through the second conducting line 4 electrically connected therewith, and thus, original wiring of the first conducting line 2 in the non-display region may be moved to the auxiliary conductive layer, so as to reduce an area or a width of the non-display region; when the array substrate is applied to a display panel, difficulty in realizing a narrow-frame display panel may be reduced.

The connecting structure 5 in FIG. 1 may be a via hole 51, and the second conducting line 4 is electrically connected with a corresponding first conducting line 2 through the via hole 51; and/or, the connecting structure 5 may be a notch, and the second conducting line 4 covers a corresponding first conducting line 2 at the notch 52. FIG. 2 shows a structural schematic diagram of an insulating layer 3, and the insulating layer 3 includes the via hole 51 and the notch 52, and of course, may only include one of the via hole 51 and the notch 52.

A Thin Film Transistor (TFT) is usually formed on the array substrate, the thin film transistor includes a source-drain metal layer and a gate metal layer, and both the source-drain metal layer and the gate metal layer include a large number of signal lines or elements (e.g. a source electrode, a drain electrode and a gate electrode of the thin film transistor). The source-drain metal layer may include a source electrode, a drain electrode, a data line and a power signal line and so on, and the gate metal layer may include a gate electrode, a gate line and a common electrode line and so on. In the embodiment, the metal conductive layer is not limited to a single metal layer, and according to structure or design requirements of different array substrates, the metal conductive layer may be a single metal layer or a combination of a plurality of metal layers; when the metal conductive layer is a combination of a plurality of metal layers, the plurality of metal layers are insulated from each other; for example, the metal conductive layer may be the source-drain metal layer, and the first conducting line 2 may be at least one type of data lines, power signal lines and grounding lines; alternatively, the metal conductive layer may be the gate metal layer, and the first conducting line 2 may be at least one type of gate lines and common electrode lines; alternatively, the metal conductive layer may be a combination of the source-drain metal layer and the gate metal layer, and a gate insulating layer may be arranged between the source-drain metal layer and the gate metal layer for realizing insulation, the first conducting line 2 may be at least one type of a plurality types of lines included in the source-drain metal layer and/or the gate metal layer, for example, the first conducting line 2 may be at least one type of the data lines, the gate lines, the power signal lines, the grounding lines, the common electrode lines, clock signal lines, gate driving signal lines, DC control signal lines and AC control signal lines. After the first conducting line 2 and the second conducting line 4 are electrically connected, a wiring space occupied by the first conducting line 2 in the non-display region of the source-drain metal layer and/or the gate metal layer may be reduced; and meanwhile, since the second conducting line 4 is used as an extending line of the first conducting line 2, antistatic capacity of the first conducting line 2 can be enhanced. Correspondingly, based on a structure of the array substrate, the insulating layer 3 located above the metal conductive layer may be a passivation layer, a planarization layer or a combination of the passivation layer and the planarization layer; the passivation layer may be any one of a silicon oxide film layer and a silicon nitride film layer or a composite film layer thereof, and the planarization layer may be a polymethyl methacrylate film layer. In addition, in the embodiment, a case in that the insulating layer 3 is located above the metal conductive layer refers to that the insulating layer 3 may be formed on the metal conductive layer and contact the metal conductive layer, or refers to that any other layer may be arranged between the insulating layer 3 and the metal conductive layer; a case in that the auxiliary conductive layer is located above the insulating layer 3 refers to that the auxiliary conductive layer may be formed on the insulating layer 3 and contact the insulating layer 3, or refers to that any other layer may be arranged between the auxiliary conductive layer and the insulating layer 3. For example, the TFT on the array substrate is of a bottom gate type, if the metal conductive layer only includes the gate metal layer, and the insulating layer 3 is a passivation layer, then a gate insulating layer, an active layer and a source-drain metal layer may be arranged between the gate metal layer and the passivation layer, sequentially; for example, the TFT on the array substrate is of a bottom gate type, if the metal conductive layer only includes the source-drain metal layer, the insulating layer 3 is a passivation layer, and the passivation layer is usually formed on the source-drain metal layer, then the insulating layer 3 is formed on the metal conductive layer and contacts it; for example, the TFT on the array substrate is of a top gate type, if the metal conductive layer only includes the gate metal layer, the insulating layer 3 is a passivation layer, and the passivation layer is usually formed on the gate metal layer, then the insulating layer 3 is formed on the metal conductive layer and contacts it; for example, the TFT on the array substrate is of a top gate type, if the metal conductive layer only includes the source-drain metal layer, and the insulating layer 3 is a passivation layer, then the active layer, the gate insulating layer and the gate metal layer may be arranged between the source-drain metal layer and the passivation layer, sequentially; for example, the TFT on the array substrate is of a top gate type, if the metal conductive layer includes the source-drain metal layer and the gate metal layer, the insulating layer 3 is a passivation layer, and the passivation layer is usually formed on the gate metal layer, then the insulating layer 3 is formed on the metal conductive layer and directly contacts it, and of course, it is necessary to arrange the gate insulating layer between the source-drain metal layer and the gate metal layer of the metal conductive layer for insulating here. The embodiment of the present disclosure only exemplary illustrates the solution, based on an actual structure of the TFT,a modification may be made according to the embodiment, which are still within the scope of the embodiment of the present disclosure.

In order to more clearly describe the structure of the array substrate provided by an embodiment of the present disclosure, in conjunction with the array substrates shown in FIGS. 3 to 5, detailed description is made as follows:

Referring to FIG. 3 (reference signs same as those of FIG. 1 have same meanings), there is shown a structural schematic diagram of a first array substrate; the array substrate includes a TFT 6, and the TFT 6 includes a gate electrode 61, a source electrode 62, a drain electrode 63 and an active layer 64, wherein, a layer where the source electrode 62 and the drain electrode layer 63 are located is a source-drain metal layer, a layer where the gate electrode 61 is located is a gate metal layer, and a gate insulating layer 7 is arranged between the source-drain metal layer and the gate metal layer. In the embodiment, the first conducting line 2 is only arranged in the source-drain metal layer, i.e., the first conducting line 2 and the source electrode 62 as well as the drain electrode 63 are arranged in a same layer, and the first conducting line 2 may be at least one type of data lines, power signal lines, grounding lines, clock signal lines and common electrode lines. Each of the plurality of the first conducting lines 2 is electrically connected with the corresponding second conducting line 4 through a via hole 51 or a notch 52. A case that the first conducting line 2 is only arranged in the gate metal layer has a structure similar to that of FIG. 3, which will not be repeated here. It should be noted that, the structure of the TFT 6 is not limited to the bottom gate type shown in FIG. 3, and may also be a top gate type or any other structure; a TFT of the top gate type or the other structure is also applicable to the embodiment, and the second conducting line 4 may be made of transparent conductive material, e.g., indium tin oxide (ITO), so as not to affect a pixel aperture ratio of the array substrate.

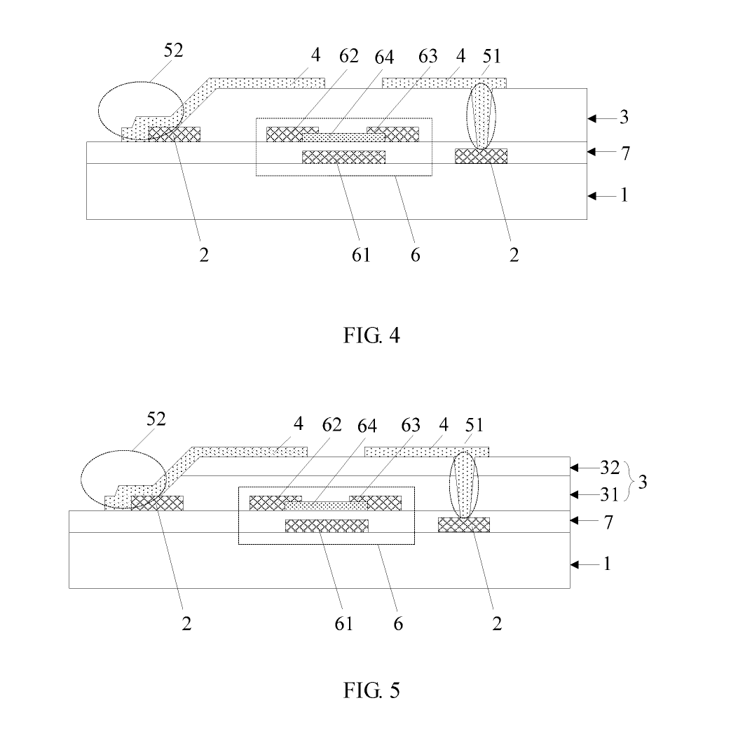

Referring to FIG. 4 (reference signs same as those of FIG. 3 have same meanings), there is shown a structural schematic diagram of a second array substrate; the array substrate includes a TFT 6, and the TFT 6 includes a gate electrode 61, a source electrode 62, a drain electrode 63 and an active layer 64, wherein, a layer where the source electrode 62 and the drain electrode layer 63 are located is the source-drain metal layer, a layer where the gate electrode 61 is located is the gate metal layer, and a gate insulating layer 7 is arranged between the source-drain metal layer and the gate metal layer. In the embodiment, the first conducting lines 2 are arranged in the source-drain metal layer and the gate metal layer, i.e., a part of the first conducting lines 2 and the source electrode 62 as well as the drain electrode 63 are arranged in a same layer,a part of the first conducting lines 2 and the gate electrode 61 are arranged in a same layer, and the second conducting line 4 may be at least one type of a data line, a power signal line,a grounding line, a clock signal line and a common electrode line. Each of the first conducting lines 2 is electrically connected with the corresponding second conducting line 4 through the via hole 51 or the notch 52. It should be noted that, the structure of the TFT 6 is not limited to the bottom gate type shown in FIG. 4, may further be a top gate type or any other structure, and a TFT of the top gate type or the other structure are also applicable to the embodiment. In the embodiment, the second conducting line 4 may be made of transparent conductive material, e.g., indium tin oxide (ITO), at a place where the second conducting line 4 is electrically connected with the first conducting line 2, the second conducting line 4 covers and protects the first conducting line 2, which can have waterproof protection and anti-oxidation protection for the first conducting line 2 located at the electrically connecting place.

The insulating layer 3 in the array substrate shown in FIG. 3 and FIG. 4 may only be a passivation layer, or may only be a planarization layer, and of course, may also be a combination of a passivation layer and a planarization layer. Referring to FIG. 5, there is shown a structural schematic diagram of a third array substrate, the array substrate shown in FIG. 5 and the array substrate shown in FIG. 4 have a similar structure, except that the insulating layer 3 of the array substrate shown in FIG.5 includes a planarization layer 31 and a passivation layer 32; of course, a stacking sequence of the planarization layer 31 and the passivation layer 32 may be reversed.

Exemplary, in order to reduce a parasitic capacitance between the auxiliary conductive layer where the second conducting line 4 is located and the metal conductive layer where the first conducting line 2 is located, the second conducting line 4 may be designed as a hollowed-out structure, and a pattern of the hollowed-out structure may be flexibly set, for example, the second conducting line 4 may be formed with square or circular holes or cut parts.

The embodiment of the present disclosure has advantageous effects as follows: the first conducting line of the metal conductive layer of the array substrate extends to the auxiliary conductive layer through the second conducting line electrically connected therewith, and thus, original wiring of the first conducting line in the non-display region may be moved to the auxiliary conductive layer, so as to reduce wiring space occupied by the first conducting line in the non-display region of the metal conductive layer, further to reduce an area or a width of the non-display region, which is conducive to realizing a narrow-frame display panel; meanwhile, since it is not necessary to adjust a line width or a line spacing in the non-display region, and it is not necessary to modify the gate driving circuit, either, the narrow-frame display panel is easily realized and has low cost.

An embodiment of the present disclosure further provides a display panel, comprising the array substrate provided by the above embodiment.

The embodiment of the present disclosure has advantageous effects as follows: the first conducting line of the metal conductive layer of the array substrate extends to the auxiliary conductive layer through the second conducting line electrically connected therewith, and thus, original wiring of the first conducting line in the non-display region may be moved to the auxiliary conductive layer, so as to reduce wiring space occupied by the first conducting line in the non-display region of the metal conductive layer, further to reduce an area or a width of the non-display region, which is conducive to realizing a narrow-frame display panel; meanwhile, since it is not necessary to adjust a line width or a line spacing in the non-display region, and it is not necessary to modify the gate driving circuit, either, the narrow-frame display panel is easily realized and has low cost.

An embodiment of the present disclosure provides a display device, comprising the display panel provided by the above embodiment.

The embodiment of the present disclosure has advantageous effects as follows: the first conducting line of the metal conductive layer of the array substrate extends to the auxiliary conductive layer through the second conducting line electrically connected therewith, and thus, original wiring of the first conducting line in the non-display region may be moved to the auxiliary conductive layer, so as to reduce wiring space occupied by the first conducting line in the non-display region of the metal conductive layer, further to reduce an area or a width of the non-display region, which is conducive to realizing a narrow-frame display panel; meanwhile, since it is not necessary to adjust a line width or a line spacing in the non-display region, and it is not necessary to modify the gate driving circuit, either, the narrow-frame display panel is easily realized and has low cost.

In addition, an embodiment of the present disclosure further provides a manufacturing method of an array substrate, comprising steps of:

Step 601: preparing a base substrate, wherein the base substrate includes a display region and a non-display region;

Step 602: forming a metal conductive layer on the base substrate, the metal conductive layer including a plurality of first conducting lines.

The metal conductive layer may include any one of a gate metal layer and a source-drain metal layer or a combination of a gate metal layer and a source-drain metal layer. Of course, if the metal conductive layer includes a combination of a gate metal layer and a source-drain metal layer, an insulating layer should be arranged between the gate metal layer and the source-drain metal layer. This also means that the first conducting lines may be formed only in the gate metal layer, or may be only formed in the source-drain metal layer, or may be formed in the gate metal layer and the source-drain metal layer.

Step 603: forming an insulating layer above the metal conductive layer, a plurality of connecting structures being formed in the insulating layer, and vertical projections of the connecting structures being located in the non-display region.

Step 604: forming an auxiliary conductive layer above the insulating layer, the auxiliary conductive layer including a plurality of second conducting lines, and the second conducting line being electrically connected with the corresponding first conducting line through the connecting structure.

It should be noted that, in the embodiment, a case in that the insulating layer 3 is located above the metal conductive layer refers to that the insulating layer 3 may be formed on the metal conductive layer and contact the metal conductive layer, or refers to that any other layer may be arranged between the insulating layer 3 and the metal conductive layer; a case in that the auxiliary conductive layer is located above the insulating layer 3 refers to that the auxiliary conductive layer may be formed on the insulating layer 3 and contact the insulating layer 3, or refers to that any other layer may be arranged between the auxiliary conductive layer and the insulating layer 3. Therefore, according to different structures or hierarchical structures of the TFT on the array substrate, based on the fabricating method provided by the embodiment, some modifications may be made, which are still within the scope of the embodiments of the present disclosure, and will not be repeated here.

The embodiment of the present disclosure has advantageous effects as follows: the first conducting line of the metal conductive layer of the array substrate extends to the auxiliary conductive layer through the second conducting line electrically connected therewith, and thus, original wiring of the first conducting line in the non-display region may be moved to the auxiliary conductive layer, so as to reduce wiring space occupied by the first conducting line in the non-display region of the metal conductive layer, further to reduce an area or a width of the non-display region, which is conducive to realizing a narrow-frame display panel; meanwhile, since it is not necessary to adjust a line width or a line spacing in the non-display region, and it is not necessary to modify the gate driving circuit, either, the narrow-frame display panel is easily realized and has low cost.

Obviously, those skilled in the art can perform various changes and modifications on the disclosure without departing from the spirit and scope of the disclosure. Hence, if those changes and modifications of the disclosure fall into the scope of the claims of the disclosure and equivalents thereof, the disclosure is also intended to contain such changes and modifications.

The present application claims priority of Chinese Patent Application No. 201510038705.7 filed on Jan. 26, 2015, the disclosure of which is incorporated herein by reference in its entirety as part of the present application.

1. An array substrate, comprising:
a base substrate, including a display region and a non-display region; and
a metal conductive layer, an insulating layer located above the metal conductive layer and an auxiliary conductive layer located above the insulating layer, formed on the base substrate, sequentially,
wherein the metal conductive layer includes a plurality of first conducting lines, and the auxiliary conductive layer includes a plurality of second conducting lines, each of the plurality of first conducting lines corresponds to at least one of the plurality of second conducting lines,
each of the plurality of second conducting lines is electrically connected with a corresponding first conducting line through a connecting structure in the insulating layer, and a vertical projection of the connecting structure is located in the non-display region.

2. The array substrate according to claim 1, wherein each of the plurality of first conducting lines at least comprises a portion located in the non-display region.

3. The array substrate according to claim 2, wherein each of the plurality of second conducting lines is electrically connected with the portion of the corresponding first conducting line located in the non-display region.

4. The array substrate according to claim 1, wherein the plurality of first conducting lines comprises at least one type of data lines, gate lines, power signal lines, grounding lines, common electrode lines and clock signal lines.

5. The array substrate according to claim 1, wherein the metal conductive layer comprises a source-drain metal layer, and the first conducting lines comprise at least one type of data lines, power signal lines and grounding lines.

6. The array substrate according to claim 1, wherein the metal conductive layer comprises a gate metal layer, and the first conducting lines comprise at least one type of gate lines and common electrode lines.

7. The array substrate according to claim 1, wherein the metal conductive layer comprises a gate metal layer and a source-drain metal layer, and the first conducting lines comprise at least one type of data lines, gate lines, power signal lines, grounding lines, common electrode lines and clock signal lines,

8. The array substrate according to claim 1, wherein the insulating layer is any one of a passivation layer and a planarization layer or a combination of the passivation layer and the planarization layer.

9. The array substrate according to claim 8, wherein the passivation layer is any one of a silicon oxide film layer and a silicon nitride film layer or a composite film layer thereof, and the planarization layer is a polymethyl methacrylate film layer.

10. The array substrate according to claim 1, wherein the connecting structure is a via hole, and the second conducting line is electrically connected with a corresponding first conducting line through the via hole.

11. The array substrate according to claim 1, wherein the connecting structure is a notch, and the second conducting line covers a corresponding first conducting line at the notch.

12. The array substrate according to claim 1, wherein the second conducting line has a hollowed-out structure.

13. The array substrate according to claim 12, wherein the second conducting line is formed to have a square or circle hole.

14. The array substrate according to claim 12, wherein the second conducting line is made of transparent conducting material.

15. A display panel, comprising:
an array substrate according to claim 1; and
an opposed substrate, cell-assembled with the array substrate.

16. A manufacturing method of an array substrate, comprising:
preparing a base substrate, wherein the base substrate includes a display region and a non-display region;
forming a metal conductive layer on the base substrate, the metal conductive layer including a plurality of first conducting lines;
forming an insulating layer above the metal conductive layer, a plurality of connecting structures being formed in the insulating layer, and vertical projections of the connecting structures being located in the non-display region; and
forming an auxiliary conductive layer above the insulating layer, the auxiliary conductive layer comprising a plurality of second conducting lines, and the second conducting line being electrically connected with the corresponding first conducting line through the connecting structure.

17. The manufacturing method of the array substrate according to claim 16, wherein each of the plurality of first conducting lines comprises at least a portion located in the non-display region.

18. The manufacturing method of the array substrate according to claim 17, wherein each of the plurality of second conducting lines is electrically connected with the portion of the corresponding first conducting line located in the non-display region.
